(19) United States
(12) Patent Application Publication
(10) Pub. No.: US 2014/0145520 A1
(43) Pub. Date: May 29, 2014

(54) CIRCUIT ARRANGEMENT HAVING A SEMICONDUCTOR SWITCH AND AN ASSOCIATED ACTUATION CIRCUIT

(71) Applicants: Karsten Handt, Burgthann (DE); Marc Hiller, Lauf an der Pegnitz (DE); Rainer Sommer, Heroldsbach (DE)

(72) Inventors: Karsten Handt, Burgthann (DE); Marc Hiller, Lauf an der Pegnitz (DE); Rainer Sommer, Heroldsbach (DE)

(21) Appl. No.: 14/233,588

(22) PCT Filed: Jul. 13, 2012
(86) PCT No.: PCT/EP2012/063824

§ 371 Date: Jan. 17, 2014

(30) Foreign Application Priority Data
Jul. 21, 2011 (DE) 10 2011 079 545.6

(51) Int. Cl. H03K 17/12

(52) U.S. Cl. CPC H03K 17/12
USPC 307/115

(57) ABSTRACT

A circuit arrangement has a series circuit which includes at least two semiconductor switches, of which each is connected to a respective actuation circuit via its control input. In the case of at least one of the actuation circuits, the switching behaviour thereof can be defined by at least one digital switching parameter. The value of the switching parameter can be varied, and therefore the switching behaviour can be adjusted during operation, that is to say between two switching processes.

The invention relates to a circuit arrangement having a semiconductor switch, which is connected via its control input to an actuation circuit, which is designed to switch the semiconductor switch as a function of a predeterminable switching signal. The circuit arrangement can be used in a frequency converter. The invention also relates to a method for the operation of a semiconductor switch with associated actuation circuit.

A circuit arrangement of this type is known from WO 2008/032113 A1. Such a circuit arrangement can, for example, be provided in a rectifier or inverter of a controllable converter, such that it can be used for the operation of a three-phase machine.

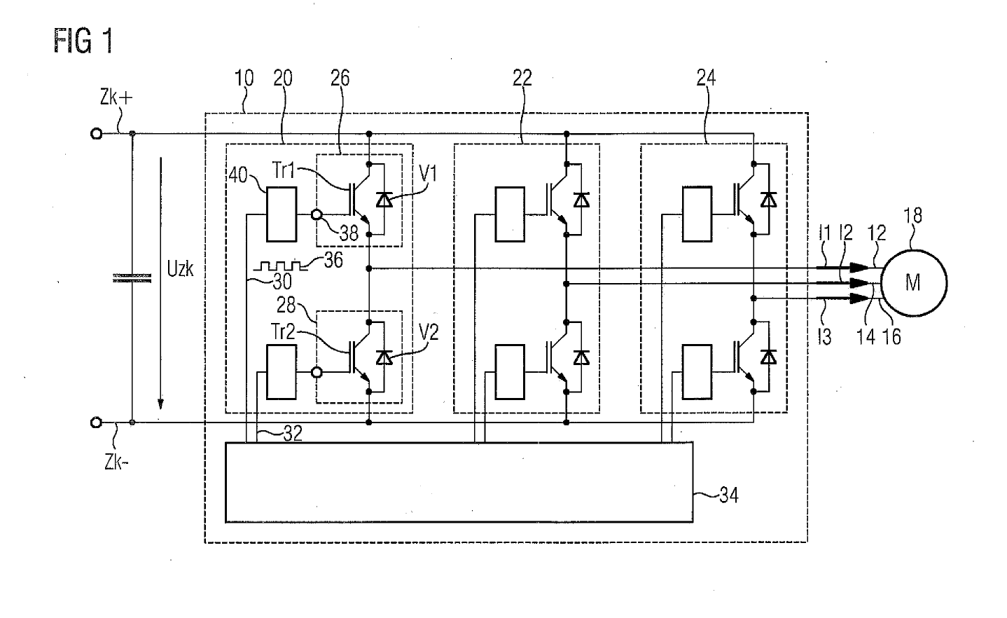

The mode of operation of a controllable converter is explained in greater detail hereinafter on the basis of FIG. 1. By means of an inverter 10, with the aid of a direct voltage Uzk, alternating currents I1, I2, I3 can be produced in phase conductors 12, 14, 16, which together form a three-phase current with which an electrical machine 18 can be operated. The direct voltage Uzk can be produced, for example, between two busbars ZK+, ZK− of an intermediate circuit of a frequency converter. To produce the alternating currents I1, I2, I3, the phase conductors 12, 14, 16 are in each case connected via a half-bridge 20, 22, 24 to the busbars ZK+, ZK− in the manner shown in FIG. 1. The manner in which the alternating currents I1, I2, I3 are produced is explained hereinafter in connection with the half-bridge 20. The same also applies accordingly to the alternating currents I2 and I3 in connection with the half-bridges 22 and 24.

The half-bridge 20 exhibits two semiconductor output switches 26, 28, each of which exhibits a transistor Tr1 and Tr2 respectively, and a diode V1 and V2 respectively connected in an anti-parallel manner with said transistor. By means of the semiconductor output switches 26, 28, the phase conductor 12 is switched once with the positive busbar ZK+ and once with the negative busbar ZK−. The transistors Tr1, Tr2, may, for example, be IGBT (insulated gate bipolar transistors) or MOSFET (metal oxide semiconductor field effect transistors). The semiconductor output switches 26, 28, are in each case connected via a control line 30, 32, to a control unit 34. The control unit 34 generates a clock signal 36, which is transferred via the control line 30 to the semiconductor output switch 26. By means of the clock signal 36, the transistor Tr1 of the semiconductor output switch 26 is switched alternately into a conductive and a blocking state. By means of the other control line 32, the control unit 34 sends a push-pull signal to the semiconductor output switch 26, such that the transistor Tr2 of the semiconductor output switch 28 is switched into push-pull mode in relation to the transistor Tr1. The alternating switching of the transistors Tr1 and Tr2 produces an alternating voltage in the phase conductor 12, and therefore the alternating current I1. To produce the three-phase current, corresponding phase-displaced clock signals are sent by the control unit 34 via further control lines to output switches of the other half-bridges 22 and 24. By means of the diodes of the semiconductor output switches, it is possible for an alternating voltage produced by the electrical machine 18 to be rectified.

The clock signals produced by the control unit 34, like the clock signal 36, are, as a rule, not present in a form such as for them to be able to actuate a semiconductor output switch directly. Accordingly, an actuation circuit 40 is therefore located upstream of a control input 38 of the semiconductor output switch 26, which, by means of an amplifier circuit (not represented in greater detail), produces a control voltage at the control input 38, as a function of the clock signal 36. The control input 38 is, in the case of a transistor, the gate or base respectively of the transistor. In the same way, a corresponding actuation circuit is arranged upstream of the semiconductor output switch 28, and corresponding actuation circuits are also arranged upstream of the output switches of the bridges 22 and 24.

In order to be able to provide a high power, e.g. more than 50 kW, for the electrical machine 18 by means of the inverter 10, without thereby obtaining excessively high current strengths of the alternating currents I1, I2, I3, a higher overall operating voltage can be used, i.e. a higher direct voltage Uzk. This possibility is, however, limited by the maximum blocking voltage capacity of the semiconductor output switches Tr1, Tr2. As well as that, operation of a semiconductor output switch at a voltage which is close to the maximum permissible reverse voltage causes a greater degree of wear on this component than operation with a markedly lower voltage.

The object of the present invention is to provide a low-maintenance switching apparatus with which a current can be switched even at relatively high powers.

The object is achieved by a circuit arrangement according to claim 1 and by a method according to claim 12. Advantageous further embodiments of the circuit arrangement according to the invention and the method according to the invention are provided in the subclaims.

The circuit arrangement according to the invention has a series circuit comprising at least two semiconductor switches, i.e. a series circuit comprising load paths of these semiconductor switches. Depending on the type of semiconductor switch used, its load path is the collector-emitter path, drain-source path, or anode-cathode path. By the use of at least two semiconductor switches in a series circuit, it is possible to switch a current even at a higher operating voltage. In order to interrupt the current, in this situation all the semiconductor switches of the series circuit are switched into a blocking state. The overall operating voltage is then divided onto the individual semiconductor switches, such that their maximum blocking voltages can be smaller than the overall operating voltage. In order for the individual semiconductor switches to be able to switch by specifying a switching signal, the semiconductor switch, in the circuit arrangement according to the invention, is connected via its control input (base or gate) to a respective actuation circuit. Each of these actuation circuits switches the semiconductor switch allocated to it in the manner already described. In this situation, each actuation circuit exhibits a specific switching behavior, for example a specific switching delay or a control response, by means of which the voltage is limited to a maximum value by way of the semiconductor switch.

With the circuit arrangement according to the invention, in the case of at least one of the actuation circuits, the switching behavior thereof can be defined by at least one digital switching parameter. The value of the switching parameter can be varied, and therefore the switching behavior can be adjusted during operation, that is to say between two switching processes. This provides the advantage that the semiconductor switches can also be operated in a gentle manner in a series circuit. Specifically, without the controllable switching behavior of the actuation circuits, the parameter scatters in the semiconductor switches or the actuation circuits would lead to an unequal voltage distribution, on the one hand during the switching processes and, on the other, in the static blocking phase, when all the semiconductor switches are switched to blocking. These asymmetries can lead to an impermissibly high voltage load on individual semiconductor switches and to an asymmetrical loss distribution among the semiconductor switches. This would therefore rapidly cause uneven wear in the semiconductor switches. By adjusting the switching behavior of the actuation circuits during operation, it is possible that the part voltages imposed on the individual semiconductor switches are put into better symmetry, switching losses are divided equally onto the semiconductor switches, and the individual semiconductor switches are protected against over-voltages. Preferably, the switching behavior of all the actuation circuits of the circuit arrangement according to the invention can be adjusted during operation.

These advantages can also be achieved by means of a method. This relates to the operation of a series circuit comprising two semiconductor switches, which in each case can be switched by way of an actuation circuit allocated to them. According to the method, a current overall value for at least one overall operating variable of the series circuit is first determined. The overall value can therefore be determined, for example, for at least one of the overall operating variables described hereinafter: A maximum value of a voltage dropping during a switching process by way of the series circuit can be determined. This voltage value can be greater than the overall operating voltage if, for example, inductances during the switching process induce an additional voltage. In exactly the same way, a voltage value of a supply voltage can be determined, i.e. the overall operating voltage. The overall operating voltage is that electrical voltage which is produced by a voltage source of which the output current is intended to be switched by the series circuit. A further value, by taking account of which the advantages described can be achieved, is a jitter value, by which a time displacement is specified between the beginning of switching processes of the actuation circuits. By means of such a time-displaced switching of the semiconductor switches as is caused by jitter, the situation can occur that the overall operating voltage, during the displaced switching of the individual semiconductor switches, drops off completely over one of these, as a result of which this is then excessively loaded.

On the basis of the determined overall value of the at least one overall operating variable, part variables are determined in each case for the individual actuation circuits; i.e. for the example of the overall operating voltage, these values could be approximately equal part voltages, which are to drop in each case over one of the semiconductor switches. The switching behavior of at least one of the actuation circuits will then be configured in accordance with the part variable determined for it. Finally, the semiconductor switches are switched by the production of a switching signal for each of the actuation circuits. By way of the configuration, at least one of the actuation circuits is set in its switching behavior in such a way that the determined part variables are actually also obtained.

There are several particularly preferred embodiments of this form of specifying part variables. For example, in one advantageous development of the circuit arrangement according to the invention with at least one actuation circuit, a voltage monitoring facility is provided, which is embodied such as to monitor a voltage dropping over the semiconductor switch actuated by the actuation circuit (e.g. a collector-emitter voltage). If the voltage is greater than a limit value, the voltage monitoring facility takes effect on the switching process in such a way that the voltage is reduced to a value less than or equal to the limit value. The limit value in this situation can be adjusted as a switching parameter of the actuation circuit in the manner described. A possible limit value is the part voltage which is derived by the dividing of the maximum voltage incurred by induction during a switching process. By means of the voltage monitoring facility with adjustable limit value, the advantage is attained that the voltage can always be divided onto the individual semiconductor switches

Another advantageous development is derived if, with at least one of the actuation circuits, a voltage end value can be adjusted as a switching parameter, which should have a voltage dropping over the semiconductor switch actuated by the actuation circuit, at the end of a switching process. The actuation circuit in this situation is configured so as to produce at least one symmetry pulse at the control input of the semiconductor switch at the conclusion of the switching process, in order to adjust the voltage end value. Due to the symmetry pulse, it is possible for the actuated semiconductor switch to briefly changes its switching state (from blocking to conducting or vice-versa), and, as a result, the part voltages dropping over the individual semiconductor switches are evened out in their voltage values.

By the voltage end value being adjustable as a switching parameter, it is also possible, even with a changeable overall operating voltage, for the part voltages to be at least approximately equal, such that the semiconductor switches are subjected to equal loading.

Another advantageous development of the circuit facility according to the invention makes provision that, with at least one of the actuation circuits, a switching delay can be adjusted as a switching parameter. This actuation circuit is in this situation configured so as to begin a switching process, delayed by the set switching delay, after receipt of the switching signal. As a result, tolerances in the actuation circuits and the power electronic switches can be evened out.

A further advantage is derived if at least one of the actuation circuits exhibits a voltage measuring facility for the measuring of a voltage which is dropping over at least one of the semiconductor switches, as well as a measurement output at which a measured value can be read off. It is then possible, by means of the circuit arrangement, to determine a current overall operating voltage.

In order to reduce an influence of an electromagnetic interference radiation on the switching behavior of one of the actuation circuits, the circuit can be arranged such as to exchange a signal via an optical waveguide connection with an external device.

A further possibility of protecting an actuation circuit against interference radiation is derived if this circuit is configured such as to exchange a signal with an external device by means of a fault-tolerant transfer protocol.

With a particularly preferred embodiment of the circuit arrangement, one of the actuation circuits is operated as a master actuation device, and the at least one other as a slave actuation device. The term “slave actuation” is understood to mean that this actuation circuit exchanges data with a signal-generating facility of the circuit arrangement, which generates the switching signals for the actuation circuits, via the master actuation device. By only the master actuation device exchanging data directly with the signal-generating facility, only very few communication lines are required in order to exchange data between the signal-generating device and the actuation circuits.

A further advantage is attained if the actuation circuits exchange data with one another via a ring bus. In that case, only very few communication lines need to be provided in order for the actuation circuits to be able to exchange data between one another. As well as this, devices of the same type can be used for the provision of data for all the actuation circuits, as a result of which the production of the circuit arrangement can be simplified and made more economical.

The invention is explained in greater detail hereinafter on the basis of exemplary embodiments. The figures show:

FIG. 1 a schematic representation of a basic structure of an inverter;

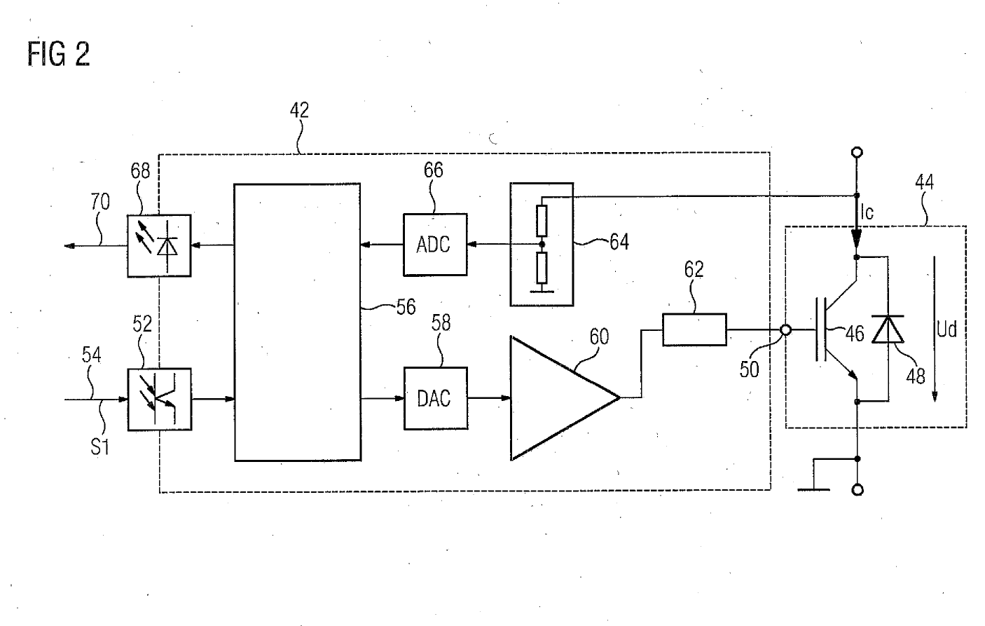

FIG. 2 a schematic representation of an actuation circuit and a semiconductor output switch, which are integrated in an embodiment of the circuit arrangement according to the invention;

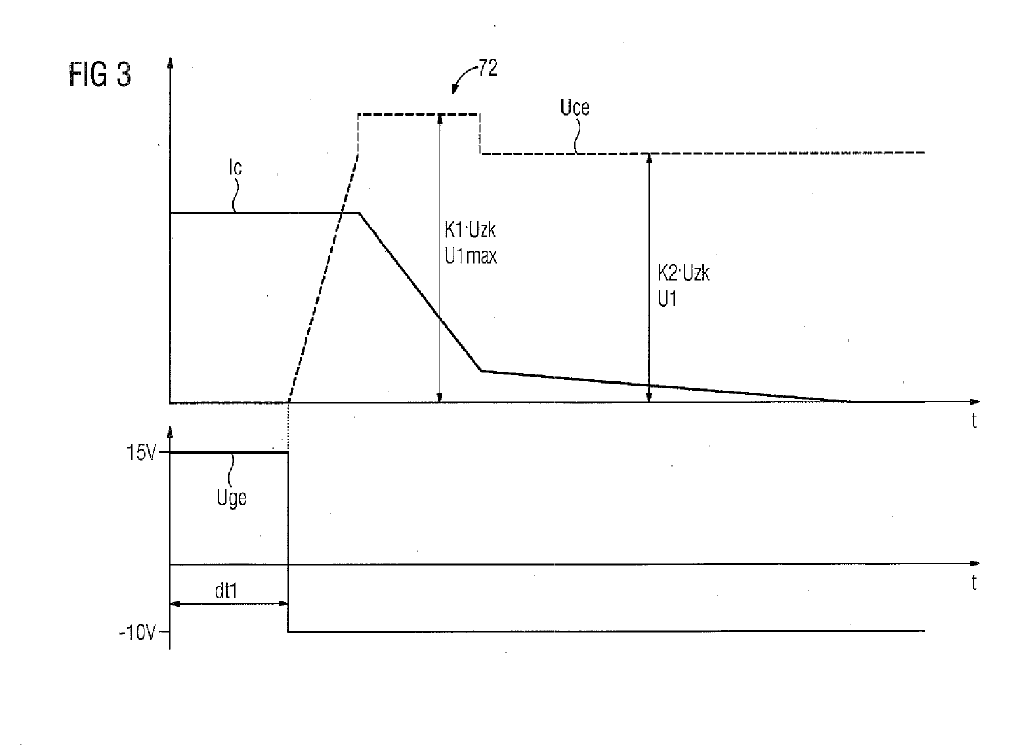

FIG. 3 two diagrams, by means of which it is illustrated what influence switching parameters have on a disconnection procedure, which can be adjusted with the actuation circuit from FIG. 2;

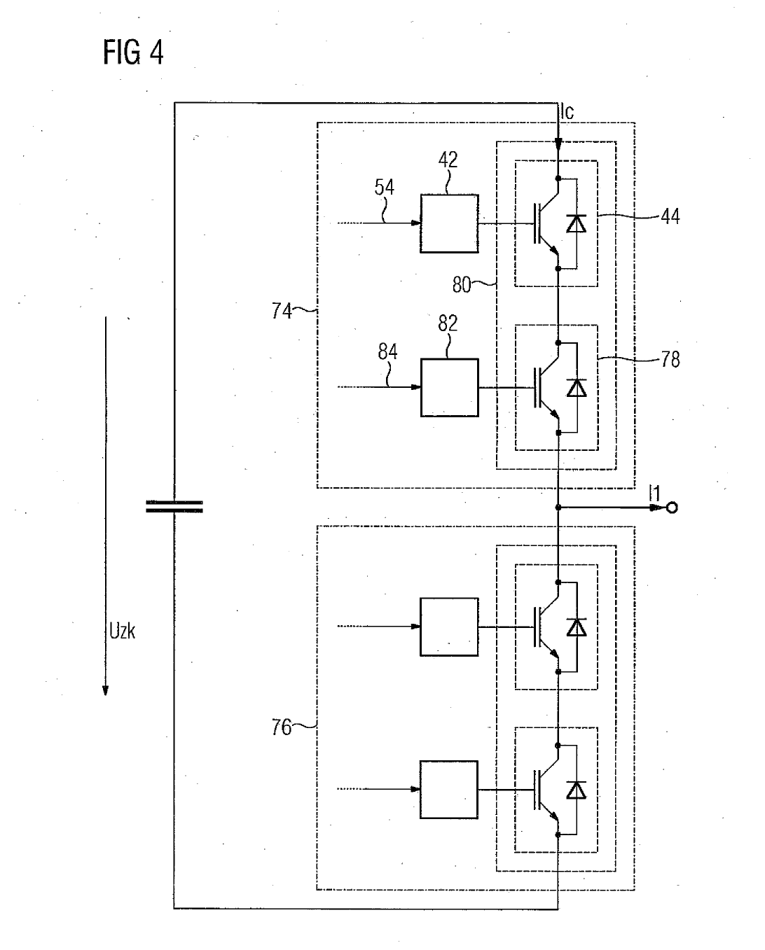

FIG. 4 a circuit diagram of two series circuits of semiconductor switches with associated actuation circuits, wherein the series circuits in each case form an embodiment of the circuit arrangement according to the invention;

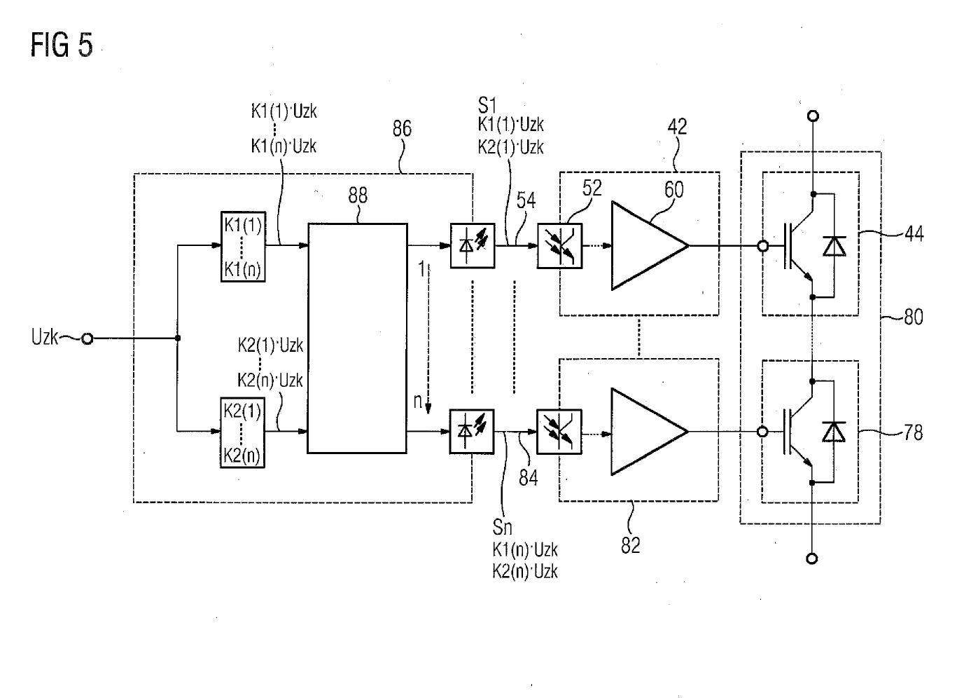

FIG. 5 to FIG. 7 in each case, a schematic representation of a further embodiment of the circuit arrangement according to the invention.

The examples represent preferred embodiments of the invention.

An actuation circuit 42 is shown in FIG. 2, which is installed in a controllable inverter (not shown in greater detail in FIG. 2) of a frequency converter. The inverter corresponds in its mode of operation to the inverter shown in FIG. 1. The actuation circuit 42 controls a semiconductor output switch 44. This exhibits a transistor 42 (in this case an IGBT) and a diode 48 connected in an anti-parallel manner herewith. Instead of the IGBT, provision can also be made for a MOSFET. In order to control the semiconductor output switch 44, the actuation circuit 42 creates a control voltage at a control input 50 of the semiconductor output switch 44. The control input 50 corresponds in this situation to the gate of the IGBT. A current Ic can be switched in a controlled manner by means of the semiconductor output switch 44.

The control voltage at the control input 50 is produced as a function of a switching signal S1, which the actuation circuit 42 receives via an opto-receiver or input opto-coupler 52, by means of which the actuation circuit 42 is connected, with a signal line 54, to an inverter control device (not shown). The signal line 54 comprises an optical waveguide. The inverter control device includes a signal-generating facility of the inverter.

The switching signal S1 is evaluated by a programmable setting facility 56. The setting facility 56 can be provided, for example, by an FGPA (field programmable gate array) or an ASIC (application-specific integrated circuit). By means of the switching signal S1, the inverter control device determines whether the semiconductor output switch 44 should be in a conductive or blocking state. The setting facility 56 generates a corresponding digital signal, to which an analog signal is generated by a digital-analog converter 58. The analog signal is amplified by an amplification circuit 60 and is transferred as a control voltage via a gate resistor 62 to the control input 50. Depending on the type of amplification circuit 60 and of the transistor 46, the actuation circuit 42 can also be operated without a gate resistor.

A digital filter or a digital control unit can also be provided in the setting facility 56, in order to produce from the switching signal S1 of the inverter control device a digital signal which is suitable for actuating the semiconductor switch 44. As well as this, it is also possible for protection functions to be provided, for example for the semiconductor output switch 44. The setting facility 56 forms a digital interface between the inverter control device and the semiconductor output switch 44.

The actuation circuit 42 exhibits a voltage measuring facility 64, with which a diode voltage Ud is acquired. The diode voltage Ud in this case corresponds likewise to the collector-emitter voltage Uce of the transistor 46. By means of an analog-digital converter 66, the acquired voltage value is converted into a digital measured value, which is evaluated by the setting facility 56. The diode voltage Ud represents a voltage dropping over the semiconductor switch 44 actuated by the actuation circuit 42.

With the actuation circuit 42, via an opto-transmitter or output opto-coupler 68 and a signal line 70, data, such as digital measured values or status information, is transferred to the inverter control device. The signal line 70 comprises an optical waveguide.

With the actuation circuit 42 provision can be made that, for the exchange of data between the inverter control device and the setting facility 56, a fault-tolerant transfer protocol can be used, such that, even in the event of a falsification of the data, for example due to an electromagnetic interference radiation, the data which was originally sent (up to a certain degree of falsification) can be reconstructed again from the falsified data. Examples of such a transfer protocol are a Barker code and a cyclic code.

If, by the switching signal S1 of the control line 54, a change in the switching state of the semiconductor switch 44 is specified by the inverter control device, i.e. from conductive to blocking or vice-versa, then a corresponding switching process is put into effect by the actuation circuit 42 by changing the control voltage at the control input 50. The switching behavior of the actuation circuit 42 is in this situation determined by switching parameters of the setting facility 56, the values of which can be changed during the operation of the actuation circuit 42. The values for the switching parameters can be transferred at the actuation circuit 42, together with the switching signal S1, via the control line 54 from the inverter control device to the setting facility 56.

On the basis of FIG. 3, it is explained hereinafter how a switching process can be influenced by the adjustment of switching parameters to a specific value.

In FIG. 3, a characteristic path of the current strength of the current Ic and the collector-emitter voltage Uce during a disconnection operation is plotted over the time t. For the interruption of the current Ic, its current strength is gradually reduced, such that the temporal course of the current strength during the switching process exhibits a final rise (derivation from Ic after the time during the disconnection). The characteristic course of the voltage Uce during the disconnection operation exhibits an overshoot 72, which is caused by a voltage which is produced by an inductance (not shown in FIG. 2) during the disconnection of the current Ic.

A voltage maximum value K1*Uzk of the collector-emitter voltage Uce represents a limit value which must not be exceeded. The voltage maximum value K1*Uzk is formed as a part voltage value from a present value of a direct voltage Uzk. The direct voltage Uzk is an operational voltage of the inverter. It is produced in an intermediate circuit of the frequency converter, to which the inverter is connected. The direct voltage Uzk is designated hereinafter as the intermediate circuit voltage Uzk. The voltage value for the intermediate circuit voltage Uzk has been determined by the inverter control as an overall operating variable.

The voltage maximum value K1*Uzk can be adjusted as a switching parameter at the setting facility 56. The voltage measuring facility 64, the analog-digital converter 66, and the setting facility 56 form in this connection a voltage monitoring facility in the form of a controller for the diode voltage Ud or Uce respectively. The desired voltage maximum value K1*Uzk is transferred by the inverter control device via the control line 54 together with the switching signal S1 to the actuation circuit 42.

A present voltage value U1max during the switching process is acquired by the voltage measuring facility 64. If the present voltage value U1max is greater than the voltage maximum value K1*Uzk, the switching process is slowed down by the setting facility 56, such that the amount of the rise in current strength characteristic of Ic is reduced.

The voltage end value K2*Uzk can be specified as a second switching parameter, which is intended to exhibit the voltage Uce at the end of the disconnection procedure. In order to attain the voltage end value K2*Uzk, provision may be made for the setting facility 56 to switch the semiconductor output switch 44 on or, several times at short intervals by the generation of a symmetry balancing pulse, to switch from the blocking to the conductive state, such that a current flow is briefly made possible, and thereby a voltage displacement in the inverter is possible. A present voltage value U1 is acquired by the voltage measuring facility 64.

As a third parameter, a switching delay value dt1 can be adjusted at the setting facility 56 as a switching parameter. The switching delay value dt1 indicates the period of time after which the setting facility 56 begins the switching process, once this has been requested by the switching signal S1 from the inverter control device. The switching process is then initiated, in that, at the control input 50, the gate-emitter voltage Uge is changed in accordance with the characteristic course shown in FIG. 3.

Shown in FIG. 4 is a half-bridge with two half-bridge branches 74, 76 of the inverter, into which the actuation circuit 42 and the semiconductor output switch 44 are integrated. The half-bridge branches 74, 76 represent in each case an embodiment of the circuit arrangement according to the invention, wherein the inverter control device (not represented) is also to be regarded as a constituent part of the circuit arrangement. The semiconductor output switch 44 is connected together with a further semiconductor output switch 78 to form a series circuit 80. As indicated in FIG. 4 by marks of omission “ . . . ”, it is possible, in addition to the two semiconductor output switches 44 and 78, for further semiconductor output switches to be contained in the series circuit 80. The total number of semiconductor output switches connected in series in the series circuit 80 is designated hereinafter by n.

By means of the two half-bridge branches 74, 76, an alternating current I1 is produced in the inverter. The alternating current I1 corresponds to the alternating current with the same reference designation in the inverter from FIG. 1. The series circuit 80 corresponds in its function to the single semiconductor output switch 26 of the inverter shown in FIG. 1. With the inverter of which the half-bridge is shown in FIG. 4, however, it is possible, by way of the series circuit 80, for the inverter to be operated with an intermediate circuit voltage Uzk which is greater than a maximum blocking voltage, which may at the most drop via one single switch of the semiconductor output switches 44, 78. In order to produce the alternating current I1, alternately one of the half-bridge branches 74, 76 is switched into a conductive state and the other half-bridge branch 76, 74 in each case is switched into a blocking state. Accordingly, almost the entire intermediate circuit voltage Uzk always drops over one of the two half-bridge branches 74, 76.

The semiconductor output switch 78 is connected via a control input to an own actuation circuit 82, which corresponds in its function to the actuation circuit 42. The actuation circuit 82 receives a switching signal Sn from the inverter control device via a control line 84.

The half-bridge branch 76 corresponds in its structure to the half-bridge branch 74. Accordingly, the elements of the half-bridge branch 76 are not explained in greater detail.

Shown in FIG. 5 to FIG. 7 is how the actuation circuits 42 and 82, and, as appropriate, also further actuation circuits, can be connected on the one hand to the inverter control device of the inverter and, on the other, can be connected to one another. In the examples shown, let it be assumed that the series circuit 80 is formed from a total number n of semiconductor output switches, of which, for the sake of clarity, in FIG. 5 to FIG. 7 in each case only the first semiconductor output switch 44 with its associated actuation circuit 42, and the last semiconductor output switch 78, with its associated actuation circuit 82 are represented.

With the variant shown in FIG. 5, the inverter control device 86 of the inverter receives a measured value of the intermediate circuit voltage Uzk from a voltage measurement facility (not represented) of the inverter. Depending on the total number n of semiconductor output switches of the series circuit 80, factors K1(1) to K1(n) are determined for the calculation of voltage maximum values K1(1)*Uzk to K1(n)*Uzk for the collector-emitter voltages of the transistors of the individual semiconductor output switches. The values form limit values, such as has already been explained in connection with FIG. 3. The voltage maximum value K1(1)*Uzk corresponds in this connection to the voltage maximum value K1*Uzk explained in connection with FIG. 3.

In accordance with the factors K1(1) to K1(n), the factors K2(1) to K2(n) are also calculated, for the calculation of voltage end values K2(1)*Uzk to K2(n)*Uzk, such as these have likewise already been explained in connection with FIG. 3. The voltage end value K2(1)*Uzk corresponds to the voltage end value K2*Uzk described in connection with FIG. 3.

The factors K1(1) to K1(n) and K2(1) to K2(n) are determined in such a way that, during the operation of the inverter, a uniform loading of the total of n semiconductor output switches of the series circuit 80 will always be incurred.

A signal-generating facility 88 of the inverter control device 86 generates a switching signal S1 to Sn for each of the actuation circuits 1 to n of the n semiconductor output switches of the series circuit 80. The actuation circuit 42, in the example shown, has the allocation number 1, and the actuation circuit 82 has the allocation number n. Via the signal lines 54 ad 84, and other signal lines only indicated in FIG. 5 by marks of omission, each of the switching signals S1 to Sn is transferred, together with the associated parameter values for the switching parameters, i.e. the voltage maximum values K1(1)*Uzk to K1(n)*Uzk and the voltage end values K2(1)*Uzk to K2(n)*Uzk, in each case to the actuation circuits for which they are intended.

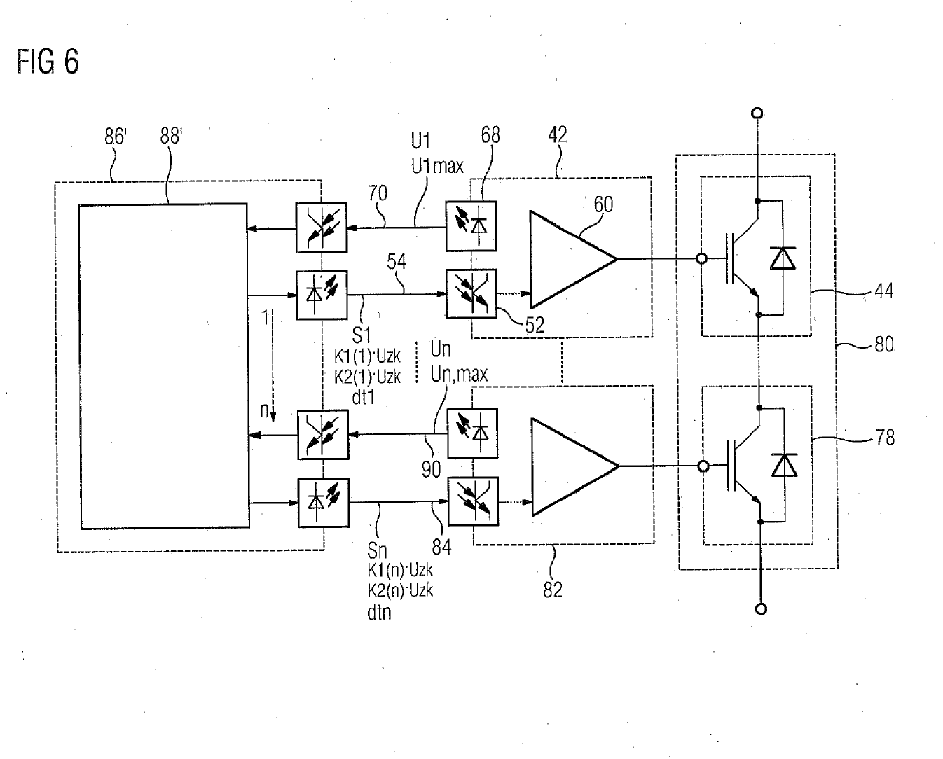

The variant shown in FIG. 6 is based on the measurement of the present voltage values U1 and U1max, as carried out by the actuation circuit 42, a measurement of corresponding present voltage values Un and Un,max, as carried out by the actuation circuit 82, and corresponding measurements of further present voltage values by the other actuation circuits of the half-bridge branch 74 (see FIG. 4). The actuation circuit 42 transfers the measured values via the signal line 70, the actuation circuit 82 via a corresponding signal line 90, and the other actuation circuits via other corresponding signal lines to an inverter control device 86′ of the variant shown in FIG. 6.

Inside the inverter control device 86′, a signal-generating facility 88′ calculates from the values U1 to Un the present intermediate circuit voltage Uzk and (in combination with the voltage values U1max to Un,max) the resultant voltage maximum values K1(1)*Uzk to K1(n)*Uzk and the voltage end values K2(1)*Uzk to K2(n)*Uazk.

These values are transferred as parameter values together with the switching signals S1 to Sn to the actuation circuits in the manner described in connection with FIG. 5. Provision can additionally be made that, by the signal-generating facility 88′, on the basis of the present voltage values received, U1 to Un and U1max to Un,max, run time differences between the individual actuation circuits are determined, and corresponding delay times dt1 to dtn are determined and likewise transferred to the actuation circuits as parameter values for corresponding switching parameters,

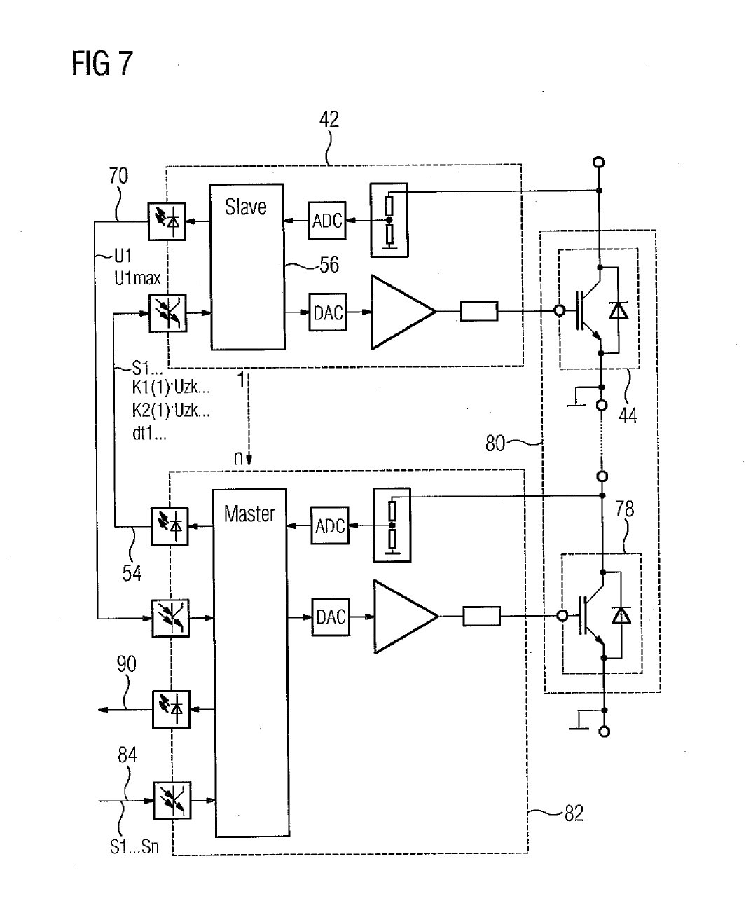

Shown in FIG. 7 is a variant in which the parameter values and the present voltage values are exchanged between the individual actuation circuits. The total of n actuation circuits 42, 82 are connected to one another in a master-slave configuration. The actuation circuit 82 is configured here as a master actuation circuit, i.e. it is the only actuation circuit of the half-bridge branch 74 which is connected to the inverter control device via its signal lines 84, 90.

The actuation circuit 82 receives the switching signals S1 to Sn for all the actuation circuits 42, 82 of the half-bridge branch 74 and transfers the received switching signals (up to that signal which is intended for itself) to the other actuation circuits 42 etc. configured as slave actuators. The communication connections between the individual actuation circuits via the signal lines 54, 70 and the other signal lines, not represented, can in this situation be established as ring bus connections.

The present voltage values U1, U1max, etc., as well as other checkback signals, are transferred to the master actuator (actuation circuit 82) by the other actuation circuits 42.

Provision can be made for voltage maximum values K1(1)*Uzk to K1(n)*Uzk and/or voltage end values K2(1)*Uzk to K2(n)*Uzk, and, as appropriate, also delay times dt1 to dtn, to be calculated by the master actuator, i.e. the actuation circuit 82. To this end the value required for the intermediate circuit voltage Uzk can in each case be determined by adding up the individual voltage values U1 to Un in the master actuator. This variant corresponds to the configuration represented in FIG. 7. In this situation, only the switching signals S1 to Sn will then have to be transferred via the signal line 84.

In a further variant of the master-slave configuration, the present voltage values U1 to Un and U1max to Un,max, as well as the other checkback signals, are transferred via the signal line 90 from the master actuator to the inverter control device. There, by a signal-generating facility which in this situation corresponds in its function to the signal-generating facility 88′, the parameter values referred to are then determined and, together with the switching signals S1 to Sn, are transferred to the master actuator.

By way of the examples, it can be shown how, by providing a digital setting facility, an actuation circuit can during operation be constantly reconfigured or parameterized respectively. This allows parameters to be transferred to the actuation circuit during operation in order to influence the operational behavior. It is therefore possible for the switching behavior of the actuation circuits to be actively influenced via signal lines, in order to influence the voltage symmetry balancing in a series circuit of semiconductor switches. Specifically, the following is made possible by the invention as described:
a digital programmable setting facility for an actuation circuit with the possibility of the reconfiguration or changing of operational parameters during operation,
a symmetry balancing of a series circuit of semiconductor switches by means of the digital setting facility by acquisition of the intermediate circuit voltage and determination of corresponding limit values or reference values respectively,
an encoded transfer of the limit values or reference values respectively, together with the switching information, to the control facilities of the individual actuation circuits by means of an optical waveguide connection,
the adoption of the limit values or reference values respectively by the control facilities, and the delimitation of the voltages dropping over the semiconductor switches to the transferred limit values and, respectively, the adjustment of these voltages to the transferred reference values,
a transfer of the limit values or reference values respectively and of the switching information, with the aid of a fault-tolerant transfer protocol in order to increase operational reliability,
the checkback of the voltage actual values via a fault-tolerant transfer protocol, and the calculation of the limit values or reference values respectively from the checked-back actual values in the central inverter control device,
an online transfer of a time delay, which can be specified per actuation circuit, for the symmetry balancing of the voltage distribution to the semiconductor switches in the series circuit.

1-9. (canceled)

10. A circuit arrangement comprising
at least two semiconductor switches connected in series, each of the semiconductor switches having a control input,
at least two actuation circuits, wherein each of the actuation circuits is connected to a control input in one-to-one correspondence and configured to switch the associated semiconductor switch as a function of a predeterminable switching signal, wherein a switching behavior of at least one of the actuation circuits is controlled during switching by at least one adjustable digital switching parameter having a value that can be adjusted during operation,
wherein the circuit arrangement is configured to switch all of the semiconductor switches into a blocking state, thereby interrupting a current, and
a) wherein at least one of the actuation circuits comprises a voltage monitoring facility configured to monitor a voltage across the associated semiconductor switch and to control the at least one actuation circuit so as to reduce the voltage across the associated semiconductor switch to a maximum value during a switching operation, when the voltage exceeds a limit value represented by the at least one adjustable digital switching parameter, and to limit the voltage to the limit value,
and/or
b) wherein the at least one adjustable digital switching parameter represents an adjustable voltage end value of at least one of the actuation circuits, with the voltage end value having at an end of the switching operation a voltage drop across the associated semiconductor switch actuated by the at least one actuation circuit, wherein the at least one actuation circuit is configured to produce at least one symmetry balancing pulse at the control input of the corresponding semiconductor switch for adjusting the voltage end value at the end of the switching operation.

11. The circuit arrangement of claim 10, wherein the at least one adjustable digital switching parameter comprises a switching delay for at least one of the actuation circuits, and whereby the at least one actuation circuit is configured to begin the switching operation with a delay commensurate with the switching delay set after receipt of the switching signal.

12. The circuit arrangement of claim 10, wherein at least one of the actuation circuits comprises a voltage measuring facility for measuring the voltage across at least one of the semiconductor switches, and a measurement output supplying a measured value.

13. The circuit arrangement of claim 10, further comprising a control facility configured to determine an overall voltage drop across all the semiconductor switches and to determine from the overall voltage a partial voltage drop for each semiconductor switch, and to transfer the determined partial voltage drop as a value of the digital switching parameter to a respective actuation circuit for each semiconductor switch.

14. The circuit arrangement of claim 10, further comprising a control facility configured to determine a value for at least one actuation circuit that causes a time offset between a start of the switching operations of the actuation circuits, and to determine from the determined value a time delay, and to transfer the determined time delay as a parameter value to one of the actuation circuits.

15. The circuit arrangement of claim 10, wherein at least one of the actuation circuits is configured to exchange a signal via an optical waveguide link with an external device.

16. The circuit arrangement of claim 15, wherein at least one of the actuation circuits is configured to exchange a signal with the external device by way of a fault-tolerant transfer protocol.

17. The circuit arrangement of claim 10, further comprising a signal-generating facility, wherein one of the actuation circuits is operated as a master actuator and at least one other actuation circuit is operated as a slave actuator, wherein the slave actuator exchanges via the master actuator data with the signal-generating facility that generates switching signals for the actuation circuits.

18. The circuit arrangement of claim 10, wherein the actuation circuits exchange data with each other via a ring bus.
